(19) United States
(12) Patent Application Publication
(10) Pub. No.: US 2011/0076858 A1
(43) Pub. Date: Mar. 31, 2011

(54) Methods for Coating the Backside of Semiconductor Wafers

(76) Inventor: Hoseung Yoo, Cypress, CA (US)

(21) Appl. No.: 12/964,074

(22) Filed: Dec. 9, 2010

Related U.S. Application Data
(63) Continuation of application No. PCT/US09/46866, filed on Jun. 10, 2009.
(60) Provisional application No. 61/060,286, filed on Jun. 10, 2008.

(51) Int. Cl. H01L 21/312

(52) U.S. Cl. 438/780; 257/E21.259

(57) ABSTRACT

The invention provides methods for depositing a coating onto the entire backside of a semiconductor wafer. The methods of the invention address the deficiencies typically associated with deposition of coatings onto the backside of semiconductor wafers. Since the methods of the invention result in wafers wherein a coating has been dispensed all the way to the edge of the wafer, there is minimal chip flying during dicing, and minimal wafer breakage and chip breakage. In addition, the methods of the invention result in a marked decrease in waste when compared to traditional spin coating methods.

### CROSS-REFERENCE TO RELATED APPLICATIONS

This application is a continuation of International Patent Application No. PCT/US2009/046866 filed Jun. 10, 2009, which claims the benefit of U.S. Provisional Patent Application No. 61/060,286 filed Jun. 10, 2008, the contents of both of which are incorporated herein by reference.

### FIELD OF THE INVENTION

The invention relates generally to coating methods for semiconductor wafers, and particularly to methods for coating the backside of semiconductor wafers with minimal coating material waste.

### BACKGROUND OF THE INVENTION

Due to the ever-increasing demand for smaller, more powerful, lightweight electronic devices, electronic manufacturers have been required to use very thin wafers for the production of active microchips. During fabrication of a semiconductor device, various processes are performed on a semiconductor wafer to form microelectronic components on the wafer. One such process involves coating of the backside (inactive face) of the thin wafer with an adhesive or support material prior to dicing. This process is commonly referred to as wafer backside coating (WBC).

Typically, the backside of a wafer is coated by one of three methods: screen printing, stencil printing, or spin coating. Each method has its advantages and disadvantages. Screen printing provides an even coating thickness with fast coating speeds, but the coating cannot be dispensed all the way to the edge of the wafer. This can result in the chip flying during dicing (die fly), as well as wafer breakage and blade breakage. Stencil printing provides various coating thicknesses with fast coating speeds, but, as with screen printing, the coating can not be dispensed all the way to the edge of the wafer, and it is difficult to obtain an even coating thickness over the entire area of the wafer. Spin coating does result in entire coverage of the wafer, but it is much slower than stencil printing or screen printing and suffers from a great deal of wasted coating, up to 40% by weight. Accordingly, there is a continuing need for improved wafer back coating processes.

### SUMMARY OF THE INVENTION

This invention is a method for depositing a coating onto the entire backside of a semiconductor wafer using the combination of stencil or screen printing and spin coating, which corrects the deficiencies associated with using only one of the typical deposition processes for coating the backside of semiconductor wafers. The stencil or screen printing operation deposits the majority of the coating, and then the remainder of the coating is deposited to the edge of the wafer with spin coating.

Thus, in one embodiment of the invention, the method comprises (a) providing a semiconductor wafer, (b) depositing the coating onto the backside of the wafer, wherein the coating is not deposited at the edge of the wafer, and thereafter (c) spinning the wafer so that the coating deposited in step (b) flows to the edge of the wafer, thereby depositing a coating on the entire backside of a semiconductor wafer.

In another embodiment of the invention, the method comprises (a) providing a semiconductor wafer, (b) stencil or screen printing the coating onto the backside of the wafer, wherein the radial extension of the stencil or screen printed coating is less than the radius of the wafer, and thereafter (c) spinning the wafer so that the coating deposited in step (b) flows to the edge of the wafer, thereby depositing a coating onto the entire backside of the semiconductor wafer.

### DETAILED DESCRIPTION OF THE INVENTION

It is to be understood that both the foregoing general description and the following detailed description are exemplary and explanatory only and are not restrictive of the invention claimed. As used herein, the use of the singular includes the plural unless specifically stated otherwise. As used herein, “or” means “and/or” unless stated otherwise. Furthermore, use of the term “including” as well as other forms, such as “includes,” and “included,” is not limiting. The section headings used herein are for organizational purposes only and are not to be construed as limiting the subject matter described.

As used herein, the term “coating” refers to any material that can be dispensed via stencil or screen printing onto the backside of a wafer.

As used herein, the phrase “coating waste” refers to the amount of coating material that is lost from the backside of the wafer after performing the methods of the invention. Coating waste can be readily determined by weighing the amount of coating on the backside of the wafer after stencil or screen printing but before spinning, and then weighing the amount of coating on the backside of the wafer after spinning. The difference is “coating waste”, measured in % by weight.

Semiconductor wafers used in the methods of the invention are typically 0.025 mm to 1 mm thick and range in diameter from 1 inch (25 mm) to 12 inch (300 mm).

In some embodiments of the invention, the coating is an adhesive. In some embodiments the adhesive is selected from the group consisting of maleimides, polyesters, (meth)acrylates, urethanes, epoxies, vinyl esters, olefinics, styrenics, oxetanes, benzoxazines, oxazolines, and the like.

In addition to screen printing or stencil printing, it is to be understood that in step (b) of the method of the invention, the coating may be deposited by any procedure that does not adequately cover the entire backside of the wafer, although screen printing and stencil printing are the two most widely used methods currently. As will be shown in the Examples, this combination of screen or stencil printing with spin coating is an efficient way to coat the entire backside surface of a semiconductor wafer without the accompanying waste attendant on using only one method.

### EXAMPLES

### Comparative Example

In a traditional spin coating process, the coating material is deposited in the center of backside of the wafer and spun at different speeds (in revolutions per minute, “rpm”) for various time periods (in seconds, “s”). The data in the following tables were generated during a traditional spin coating process using a seven step protocol, with a different speed and time interval for each.

SPIN COATING PROTOCOL

| Step 1 | Step 2 | Step 3 | Step 4 | Step 5 | Step 6 | Step 7 |
|---|---|---|---|---|---|---|
| 300 rpm | 400 rpm | 500 rpm | 700 rpm | 1000 rpm | 1250 rpm | 150 rpm |
| 20 s | 20 s | 20 s | 20 s | 40 s | 30 s | 5 s |

| Comparative | Weight (grams) | Weight (grams) | |
|---|---|---|---|
| Example | Before Step 1 | After Step 7 | Percent Waste |
| 1 | 3.905 | 2.435 | 37.6 |
| 2 | 3.945 | 2.330 | 40.9 |
| 3 | 3.895 | 2.330 | 40.2 |
| 4 | 3.992 | 2.363 | 40.8 |
| 5 | 3.704 | 2.326 | 37.2 |

### Invention Example

The data in the following table were generated using the methods of the invention. It can be seen that invention methods produce significantly less coating material waste than traditional WBC methods.

| | | | | WBC | WBC | |
|---|---|---|---|---|---|---|
| | | After | After | weight | weight | |
| | Bare | stencil | spin | after | after spin | |
| | wafer wt | printing | coat | printing | coating | Percent |
| | (grams) | (grams) | (grams) | (grams) | (grams) | waste |
| Sample 1 | 29.04 | 30.73 | 30.58 | 1.69 | 1.54 | 8.6 |
| Sample 2 | 29.11 | 30.49 | 30.39 | 1.38 | 1.28 | 7.2 |
| Sample 3 | 29.16 | 30.68 | 30.54 | 1.52 | 1.38 | 8.9 |

The invention provides novel methods for depositing a coating onto the entire backside of a semiconductor wafer. The methods of the invention result in wafers coated all the way to the edge, thereby minimizing problems such as chip flying and wafer breakage during dicing of the wafer. In addition, the methods of the invention result in typically less than 10% coating waste, compared to 30-40% seen with traditional spin coating methods.

What is claimed is:

1. A method for depositing a coating onto the entire back side of a semiconductor wafer, comprising
(a) providing a semiconductor wafer,
(b) depositing the coating onto the backside of the wafer, wherein the coating is not deposited at the edge of the wafer, and thereafter
(c) spinning the wafer so that the coating deposited in step (b) flows to the edge of the wafer, thereby depositing a coating on the entire backside of a semiconductor wafer.

2. The method of claim 1, wherein the coating is an adhesive.

3. The method of claim 2, wherein the adhesive comprises maleimides, polyesters, (meth)acrylates, urethanes, epoxies, vinyl esters, olefinics, styrenics, oxetanes, benzoxazines, or oxazolines.

4. The method of claim 1, wherein the coating is deposited in step (b) via screen printing or stencil printing.

5. A method for depositing a coating onto the entire back side of a semiconductor wafer, comprising
(a) providing a semiconductor wafer,
(b) depositing the coating onto the backside of the wafer, wherein the radial extension of the deposited coating is less than the radius of the wafer, and thereafter
(c) spinning the wafer so that the coating deposited in step (b) flows to the edge of the wafer, thereby depositing a coating onto the entire backside of the semiconductor wafer.

6. The method of claim 5, wherein the coating is an adhesive.

7. The method of claim 6, wherein the adhesive is selected from the group consisting of maleimides, polyesters, (meth)acrylates, urethanes, epoxies, vinyl esters, olefinics, styrenics, oxetanes, benzoxazines, or oxazolines.

8. The method of claim 5, wherein the coating is deposited in step (b) via screen printing or stencil printing.

9. A method for minimizing coating waste when coating the backside of a semiconductor wafer, comprising
(a) providing a semiconductor wafer,
(b) depositing the coating onto the backside of the wafer, wherein the radial extension of the coating is less than the radius of the wafer, and thereafter
(c) spinning the wafer so that the coating deposited in step (b) flows to the edge of the wafer, thereby minimizing coating waste.

10. The method of claim 9, wherein the coating waste is less than 10% of the total amount of coating dispensed onto the backside of the wafer.
